(19) United States
(12) Patent Application Publication
(10) Pub. No.: US 2026/0082680 A1
(43) Pub. Date: Mar. 19, 2026

(54) SEMICONDUCTOR TRANSISTOR DEVICE AND METHOD OF MANUFACTURING THE SAME

(71) Applicant: Infineon Technologies Austria AG, Villach (AT)

(72) Inventors: Thomas Aichinger, Faak am See (AT); Vice Sodan, Villach (AT); Michael Hell, Erlangen (DE); Dethard Peters, Höchstadt (DE); Wolfgang Bergner, Klagenfurt am Wörthersee (AT)

(21) Appl. No.: 19/322,764

(22) Filed: Sep. 9, 2025

(30) Foreign Application Priority Data
Sep. 18, 2024 (DE) 102024208938.9

(51) Int. Cl. H10D 84/00; H10D 8/00; H10D 8/01; H10D 30/01; H10D 30/66; H10D 62/10; H10D 62/40; H10D 62/832

(52) U.S. Cl. CPC H10D 84/143; H10D 8/045; H10D 8/422; H10D 30/0297; H10D 30/668; H10D 62/103; H10D 62/405; H10D 62/8325

(57) ABSTRACT

A semiconductor transistor device includes: a gate trench in a SiC semiconductor body; a channel region at a first side wall of the trench; and a diode region at a second side wall of the trench, the side walls lying opposite to each other in a transverse direction. As seen in a vertical cross-section perpendicular to the side walls, a first surface normal n₁, perpendicular to the first side wall and pointing towards the channel region, is rotated between 174° to 178° in relation to a 4H-SiC Crystal a-direction, and a second surface normal n₂, perpendicular to the second side wall and pointing towards the diode region, is rotated between −2° to −6° in relation to the 4H-SiC Crystal a-direction, or n₁ is rotated between 178° to 182° in relation to a 4H-SiC Crystal m-direction and n₂ is rotated between −2° to 2° in relation to the 4H-SiC Crystal m-direction.

### TECHNICAL FIELD

The present disclosure relates to a semiconductor transistor device with a silicon carbide semiconductor body.

### BACKGROUND

Silicon carbide (SiC) has a comparably wide band gap, e.g. compared to silicon. This can for instance facilitate high-voltage and/or high-current capabilities, e.g. be of interest for power semiconductor devices. These find applications in various fields, such as high-voltage DC transmission, for instance in offshore wind farms or the like.

### SUMMARY

Examples of the present application are directed at an advantageous semiconductor transistor device with a SiC semiconductor body.

The semiconductor transistor device may comprise a gate trench which extends into the SiC semiconductor body, wherein a channel region of the device is arranged at a first side wall of the gate trench. At a second side wall of the gate trench, which lies opposite to the first side wall in a transverse direction, a diode region of the device may be arranged. In the following paragraphs, the orientation of the first and second side wall of the gate trench is discussed for a cross-sectional view and with respect to a first surface normal, which is perpendicular to the first side wall and points towards the channel region, and a second surface normal, which is perpendicular to the second side wall and points towards the diode region.

The first and second surface normal respectively lie in the SiC semiconductor body (not in the gate trench), i.e. respectively point away from the gate trench.

In an embodiment (i), the first surface normal is rotated between at least 174° and/or at most 178° in relation to a 4H-SiC Crystal a-direction. This can, for example, reduce an on-resistance (Rₒₙ), e.g. in comparison to a first side wall arranged in parallel to the crystal a-plane. The second surface normal may be rotated by at least −2° and/or at most −6° in relation to the 4H-SiC Crystal a-direction. The rotation of the first and second surface normal is considered in a vertical cross-section perpendicular to the side walls of the gate trench, wherein the negative sign indicates a clockwise rotation, and the positive sign indicates a counterclockwise rotation. In case of the embodiment (i), the rotation respectively refers to 4H-SiC Crystal a-direction (<11-20> direction), wherein a viewing direction on the vertical cross-section may lie opposite to the <1-100> direction.

In an alternative embodiment (ii), the first surface normal is rotated by at least −2° and/or at most 2° in relation to a 4H-SiC Crystal m-direction. The second surface normal may be rotated by at least 178° and/or at most 182° to the 4H-SiC Crystal m-direction. Therein, in case of the embodiment (ii), the rotation respectively refers to 4H-SiC Crystal m-direction (<1-100> direction), and a viewing direction on the vertical cross-section may lie opposite to the <11-20> direction.

Further embodiments and features are provided in the dependent claims and this description and the figures. Therein, the individual features shall be disclosed independently of a specific claim category, the disclosure relates to apparatus and device aspects, but also to method and use aspects. If, for instance, a device manufactured in a specific way is described, this is also a disclosure of a respective manufacturing process, and vice versa. In general words, an approach of this disclosure may be to arrange a side wall of the gate trench, at which the channel region is arranged, either with a slight tilt to the 4H-SiC Crystal a-plane (e.g. 2°-6°, taken as an absolute value) or to arrange it basically in parallel to the 4H-SiC Crystal m-plane (e.g. tilted by not more than 2°, taken as an absolute value).

For example, in case of an asymmetric cell design, the diode region may be arranged at the second side wall of the gate trench. In comparison to a body region of the device, in which the channel region is formed, the diode region may have a greater vertical extension, e.g. extend to a greater vertical depth than the channel region. It can for instance extend deeper than the gate trench, a lower end of the diode region being for instance arranged deeper, i.e. at a larger distance from a first side of the SiC semiconductor body, than a lower end of the gate trench. Alternatively or in addition, the diode region may have a higher doping concentration than the body region, but have for instance the same doping type. In operation of the semiconductor transistor device, the diode region may operate as a free wheeling diode, e.g. conduct the current in the forward direction from source to drain and shield the gate trench and the channel from too high electric fields in blocking mode.

In the transverse direction, in which the first and second side wall of the gate trench lie opposite to each other, a plurality of device cells may be arranged consecutive, the transverse direction being for instance a direction of a translational symmetry of the device cells. In a length direction, which may lie perpendicular to the transverse direction, the gate trench may have its length extension. A vertical direction may run essentially perpendicular to these lateral directions (i.e., the transverse direction and the length direction), an extension of the SiC semiconductor body in the vertical direction being for instance small compared to its extension in the lateral directions.

The gate trench may extend from a first side, which may also be referred to as a “frontside”, of the SiC semiconductor body into the SiC semiconductor body. At a vertically opposite second side of the SiC semiconductor body, a load region of the device may be arranged, for instance a drain region. With a source region arranged at the first side of the SiC semiconductor body and a body region below the source region, a vertical current flow in the channel region may be realized, wherein the gate electrode is disposed laterally aside the channel region in the gate trench, e.g. capacitively coupling to the channel region via a gate dielectric.

The source region and drain region may have a first doping type, the body region an opposite second doping type. The diode region may have the second doping type as well, i.e. same doping type like the body region. The device may additionally comprise a drift region vertically between the body region and the drain region, e.g. having the same doping type like the drain region but with a lower doping concentration. In embodiments of this application, the first doping type is n-type and the second doping type is p-type.

The SiC semiconductor body may be of the hexagonal 4H polytype (4H-SiC). An off-axis angle of the SiC semiconductor body may be in a range from 2° to 6°, typically 4°. The first side of the SiC semiconductor body then may be ribbed such that sections of the first side may be tilted with respect to the horizontal direction. For example, a main crystal axis (e.g. the <0001>-axis) of the SiC semiconductor body may enclose an angle (e.g. the off-axis angle) with respect to the vertical direction. The SiC semiconductor body may comprise a SiC semiconductor substrate, e.g. in combination with one or a plurality of epitaxial SiC semiconductor layers thereon.

In an embodiment, the gate trench, which has the side wall or side walls oriented according to the first embodiment (i), i.e. with respect to the 4H-SiC Crystal a-direction, has its length extension along a <1-100> direction. In the length direction, which lies perpendicular to the transverse direction, the gate trench may have a significantly larger extension than in the transverse direction, e.g. at least five times or ten times larger. As seen in a top view in the vertical direction, the gate trench may have a straight extension, i.e. in parallel to the <1-100> direction. As discussed above, for instance a die or wafer with a 4° off-axis cut may be used.

In an embodiment, the first and second side wall of the gate trench of the first embodiment (i) are tilted by the same angle to the 4H-SiC Crystal a-plane. Therein, the respective tilt angle between the respective side wall of the gate trench and the 4H-SiC Crystal a-plane is taken as an absolute value (independently of a tilt direction), wherein the smallest angle enclosed respectively between the 4H-SiC Crystal a-plane and the respective side wall is considered.

In an embodiment, which relates to a gate trench with a side wall or side walls oriented according to the first embodiment (i), the first surface normal is rotated by at least 175° and/or most 177° in relation to the 4H-SiC Crystal a-direction. By way of example, the first surface normal, which points towards channel region, may be rotated by 176° to the 4H-SiC Crystal a-direction. Alternatively or in addition, the second surface normal, which points towards the diode region, may be rotated by at least −3° and/or at most −5° in relation to the 4H-SiC Crystal a-direction. By way of example, it may be rotated by −4° in relation to the 4H-SiC Crystal a-direction.

In an embodiment, which relates to a gate trench having the side wall or side walls oriented according to the second embodiment (ii), the gate trench has a length extension along a <11-20> direction of the 4H-SiC Crystal, i.e. in the 4H-SiC Crystal a-direction. In the length direction, the gate trench may have a significantly larger lateral extension than in the transverse direction, which lies perpendicular thereto, see the remarks on the first embodiment (i) above.

In an embodiment, an insulating layer is arranged on the first side of the semiconductor body, wherein a contact plug intersects the insulating layer vertically. The contact plug, which is arranged in a contact hole in the insulating layer, may for instance connect a region or element in the semiconductor body to a metallization above. It may be made of a separate material, e.g. be formed in a previous step, or be made of the same material like a metallization arranged on the insulating layer, e.g. be formed together with the metallization.

In an embodiment, a side wall of the contact hole, as viewed in a vertical cross-section, forms an angle δ of at most 10° to the vertical direction (which lies perpendicular to the lateral directions, see above). In detail, this angle δ may be taken as smallest angle between the vertical direction and the side wall of the contact hole as seen in the vertical cross-section. By way of example, the angle δ may be taken between the vertical direction and a straight line fitted into the side wall of the contact hole as seen in the vertical cross-section (linear fit), for instance in case of a curved or bulged side wall. The sectional plane can, for instance, lie parallel to a translational symmetry direction of the device cells and/or parallel to the transverse direction and/or perpendicular to the side walls of the gate trench.

The angle δ being at most 10° can for instance allow for a reduced contact hole width at an upper end (e.g. in an upper surface of the insulating layer), and still provide a sufficiently large contact area to the semiconductor body. In other words, it may allow for a cell shrink, wherein a negative impact on the electrical contact properties can be reduced or avoided. Further upper limits of the angle δ may for instance be at most 8°, 6°, 4° or 2°, wherein a side wall parallel to the vertical direction is possible as well (0°). This embodiment relating to a contact hole side wall having a limited tilt to the vertical direction (δ≤10°) shall also be disclosed independently of an orientation of the gate trench with respect to the crystal directions/planes. In other words, it shall be disclosed:

A semiconductor transistor device, comprising: a silicon carbide (SiC) semiconductor body; an insulating layer on a first side of the SiC semiconductor body; a contact plug in a contact hole extending through the insulating layer; wherein a side wall of the contact hole, as viewed in a vertical cross-section, forms an angle δ of at most 10° to a vertical direction.

In an embodiment, both side walls of the contact hole, as viewed in the vertical cross-section, lie basically parallel to each other and to the vertical direction. Therein, “basically parallel” may refer to a tilt of not more than 1°. As discussed above, the vertical direction lying perpendicular to the lateral directions, e.g. to the length and transverse direction, may enclose an off-axis angle with a main crystal axis (e.g. <0001> axis), for instance of 4°.

In an embodiment, a lateral distance between a lower end of the contact plug and an upper end of the gate electrode, which is arranged in the gate trench, is at most 500 nm, e.g. at most 400 nm. A possible lower limit can for instance be at least 100 nm, a further lower limit being for instance at least 150 nm. In detail, the lateral distance may be taken in the vertical cross-section, e.g. as a lateral clearance between the lower end of the contact plug and the upper end of the gate electrode (which do not necessarily lie on the same vertical height).

Any of the embodiments specifying the contact plug/contact hole more in detail, as discussed in the paragraphs above, shall be disclosed in combination with the orientation of the side walls of the gate trench with respect to the Crystal structure, but also independently therefrom.

As discussed above, the semiconductor transistor device may comprise a load terminal, e.g. source region, at the first side of the SiC semiconductor body, e.g. in combination with a load terminal, for instance drain region, at the second side of the SiC semiconductor body. The device may comprise a plurality of device cells, e.g. arranged consecutive in the transverse direction (e.g. translational symmetrical). Each device cell may comprise the elements/regions discussed for the device as a whole, e.g. load regions at opposite sides of the semiconductor body, a diode region, and so on. Therein, the device cells arranged consecutive may be referred to as a first device cell, a second device cell and so on, the first and second device cell arranged aside each other.

In an embodiment, a contact plug makes electrical contact to the load terminal (“first load terminal”), e.g. source region, of the first device cell and to the diode region (“second diode region”) of the second device cell. In other words, a first contact area of the contact plug makes electrical contact to the first load terminal and a second contact area of the contact plug makes electrical contact to the second diode region. As mentioned, the first and second device cells are arranged aside each other, the first load terminal and the second diode region being arranged aside each other as well, e.g. directly adjacent to each other.

In an embodiment, the first contact area and the second contact area have a different size. In other words, the contact plug may be arranged non-centric on the first load terminal and the second diode region. The non-centric arrangement, e.g. non-symmetric centering of the first and second contact area, can for instance account for different first and second doping type resistances, i.e. n-and p-contact resistances. This may allow for a shrink of the device cells while maintaining a good Rₒₙ (depends on n-contact) and forward voltage (depends on p-contact).

This embodiment, i.e. the contact plug having contact areas with a different size towards the first load terminal and the second diode region, shall also be disclosed independently of the gate trench having side walls in a specific orientation with respect to the crystal structure. In detail, it shall be disclosed:

A semiconductor transistor device, comprising: a silicon carbide (SiC) semiconductor body; a first load terminal of a first device cell at a first side of the SiC semiconductor body; a contact plug contacting the first load terminal; a second diode region of a second device cell; wherein the contact plug also contacts the second diode region, the contact plug having a first contact area to the first load terminal and a second contact area to the second diode region, and wherein the first contact area and the second contact area have a different size.

In an embodiment, the first contact area is larger than the second contact area. By way of example, the first contact area may define the n-contact resistance, and the second contact area may define the p-contact resistance. The first contact area may be larger by at least 20%, e.g. at least 30%, than the second contact area. A possible upper limit may be at the most 150%, a further upper limit being for instance at most 100%.

In an embodiment, the contact plug has, taken at its lower end, a lateral width of at least 600 nm, further lower limits being for instance at least 700 nm or 800 nm. In other words, the first contact area and the second contact area together may have a total width of at least 600 nm. By way of example, possible upper limits of the lateral width may be 3 μm, 2 μm and 1.5 μm.

The embodiments discussed in the paragraphs above, which relate to the first and second contact area having different sizes, shall be disclosed independently of the orientation of the side walls of the gate trench, but also in combination with it. Further, they shall be disclosed independently of the contact hole having a side wall with an angle δ to the vertical direction, but also in combination therewith. In other words, the contact plug having the first and second contact area with different sizes may be arranged in a contact hole, the side wall of which forms an angle δ of at most 10° to the vertical direction, see the description above for further details.

In an embodiment, an insulating layer on the first side of the semiconductor body comprises a borophosphosilicate (BPSG) layer, wherein a boron content may be at most 3%, e.g. 1%-3% (percentage by mass, i.e. wt. %). In other words, the insulating layer may be or comprise a doped layer, but with a rather small doping concentration. In general, as an alternative, the insulating layer may comprise an undoped silicate glass (USG) layer or a phosphosilicate glass (PSG) layer (0 % boron content).

Alternatively or in addition, the insulating layer may comprise a BPSG layer with a phosphorus content of at most 4%, e.g. 2%-4% (wt. %, see above). By way of example, the same BPSG layer may have a boron content of 1%-3%, and a phosphorus content of 2%-4%. In an embodiment, a method of manufacturing a semiconductor transistor device may comprise: etching a gate trench into a silicon carbide (SiC) semiconductor body; and/or etching a contact hole into an insulating layer on a first side of the SiC semiconductor body; and/or forming a contact plug.

As to possible further details, reference is made to the description above and the exemplary embodiments.

### BRIEF DESCRIPTION OF THE DRAWINGS

Below, the semiconductor transistor and method of manufacturing are explained in further detail by means of exemplary embodiments. Therein, the individual features can also be relevant in a different combination.

FIG. 1 shows a cross-sectional view of a semiconductor transistor device;

FIG. 2a shows a gate trench and illustrates an arrangement of its side walls with respect to the crystal structure;

FIG. 2b shows another gate trench and illustrates an arrangement of its side walls with respect to the crystal structure;

FIGS. 3a and 3billustrate different planes and directions in a hexagonal crystal structure;

FIG. 4 shows a detailed view of a contact plug in a contact hole in an insulating layer;

FIG. 5 shows a detailed view of a contact plug and a gate electrode;

FIG. 6 illustrates contact areas formed by a contact plug;

FIG. 7 summarizes some manufacturing steps in a flow diagram.

### DETAILED DESCRIPTION

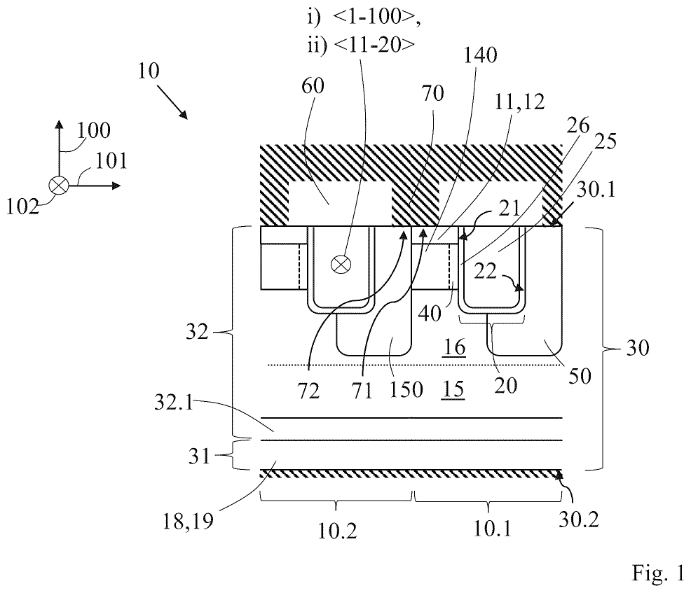

FIG. 1 shows a semiconductor transistor device 10 in a vertical cross-section, wherein the sectional plane lies parallel to a vertical direction 100 and to a transverse direction 101. The device 10 comprises a plurality of device cells 10.1, 10.2, wherein the reference numerals are mainly provided for a first device cell 10.1, though the following description applies analogously for a second device cell 10.2. The device cells 10.1, 10.2 are formed in a silicon carbide (SiC) semiconductor body 30, which comprises a SiC semiconductor substrate 31, on which a plurality of epitaxial SiC layers 32 are formed.

The device 10 is a vertical device, which comprises load terminals 11, 18 at vertically opposite sides of the SiC semiconductor body 30. In detail, a first load terminal 11 is formed at the first side 30.1 of the SiC semiconductor body 30, which is a source region 12 in the example shown. At the second side 30.2 of the SiC semiconductor body 30, a second load terminal 18, e.g. a drain region 19, of the device 10 is arranged. From the first side 30.1, a gate trench 20 extends into the SiC semiconductor body 30. A gate electrode 25 is disposed in the gate trench 20, that capacitively couples to a channel region 40 via a gate dielectric 26. The channel region 40 is part of a body region 140, which is arranged below the first load terminal 11. By applying a gate voltage to the gate electrode 25, a channel formation and current flow through the channel region 40 can be controlled, i.e. a vertical current flow between the load terminals 11, 18.

The channel region 40 is arranged at a first side wall 21 of the gate trench 20. At a second side wall 22 of the gate trench 20, which lies opposite with respect to the transverse direction 101, a diode region 50 is formed, e.g. having a second doping type like the body region 140. The load terminals 11, 18, e.g. source region 12 and drain region 19, may have a first doping type. The device 10 may additionally comprise a drift region 15 above the drain region 19, e.g. have the first doping type as well, but with a lower doping concentration. Above the drift region 15, a current spread region 16 may be arranged, having the first doping type as well, but with a higher doping concentration than the drift region 15. In the example shown, the SiC semiconductor body 30 additionally comprises a buffer layer 32.1 between the SiC semiconductor substrate 31 and the drift region 15.

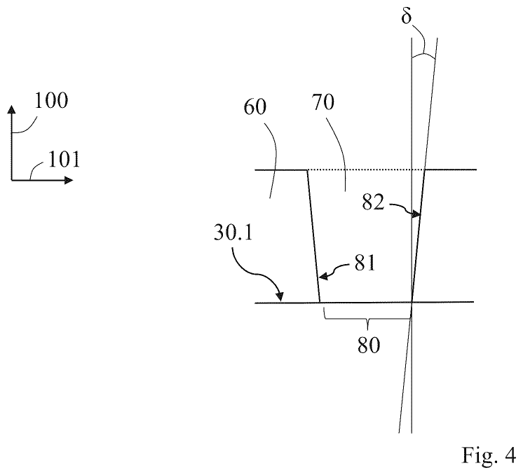

On the first side 30.1 of the SiC semiconductor body 30, an insulating layer 60 is formed. The insulating layer 60 may be or comprise a BPSG layer, e.g. with a boron content of 1%-3% and a phosphorus content of 2%-4%. The insulating layer 60 is opened locally, wherein contact plugs 70 extend through the insulating layer 60 and form an electrical contact to the SiC semiconductor body 30, i.e. with a first contact area 71 to the first load terminal 11, and with a second contact area 72 to a diode region of the second cell 10.2, i.e. to the second diode region 150 (see FIGS. 4-6 in further detail).

In a length direction 102, which lies perpendicular to the drawing plane, the gate trench 20 has its length extension. With respect to the crystal structure of the SiC semiconductor body 30, the gate trench 20 can have different orientations, wherein the length direction 102 lies parallel to the <1-100> direction in case of a first embodiment (i) and lies parallel to the <11-20> direction in case of a second embodiment (ii).

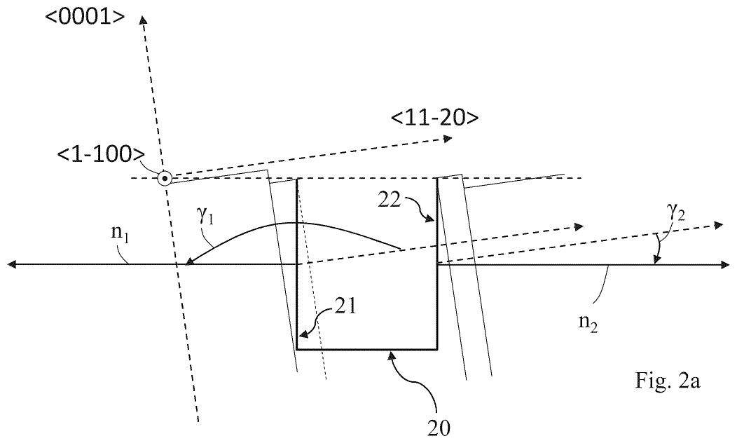

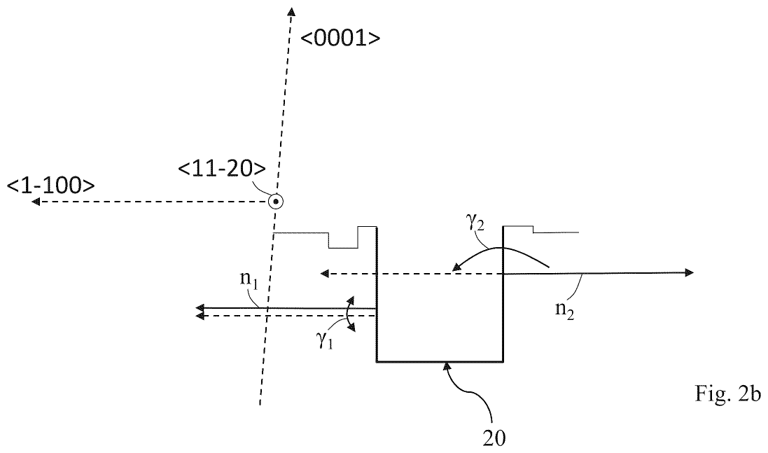

FIG. 2a illustrates the gate trench of the first embodiment (i) in further detail. A first surface normal n₁ lies perpendicular to the first side wall 21 and points towards the channel region (see FIG. 1), and a second surface normal n₂ lies perpendicular to the second side wall 22 and points towards the diode region (see FIG. 1). Further, crystal directions of the 4H-SiC Crystal structure are shown in FIG. 2, i.e. the <0001>direction (main crystal axis) and the <11-20> direction (a-direction). The viewing direction is opposite to the <1-100> direction.

The first surface normal n₁ is rotated counterclockwise by an angle γ₁ in relation to the <11-20> direction, wherein γ₁ is between 174°-178°, e.g. 176 ° in the example shown. The second surface normal n₂ at the second side wall 22 is rotated clockwise by an angle γ₂ with respect the <11-20> direction, which is between −2° to −6°, e.g. −4° in the example shown.

A 4H-SiC Crystal ingot, for instance, may be cut at an off-axis angle α with respect to the (0001)-plane to obtain a wafer substrate. During a thermal treatment of the wafer substrate, silicon and carbon atoms rearrange along the crystal directions, such that a serrated surface with long flat first surface section parallel to the <11-20> crystal direction and short deep second surface sections, is formed, see FIG. 2 for illustration. When an epitaxial layer is deposited on such a wafer substrate, the surface structure may order the impinging silicon and carbon atoms in a way such that the grown epitaxial layer continuous the 4H-SiC Crystal structure.

FIG. 2b illustrates the gate trench 20 of the second embodiment (ii) in further detail. The first surface normal n₁ is rotated by an angle γ₁, which is at least −2° and/or at most 2° in relation to the m-direction (<1-100> direction). The second surface normal n₂ is rotated by an angle γ₂, which is at least 178° and/or at most 182° in relation to the m-direction. The viewing direction is opposite to the <11-20> direction.

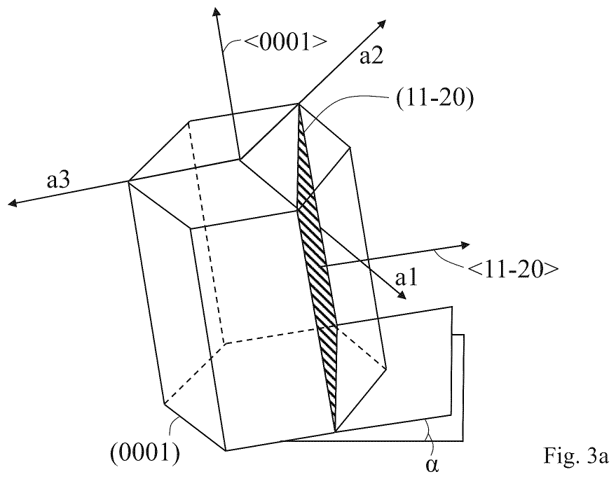

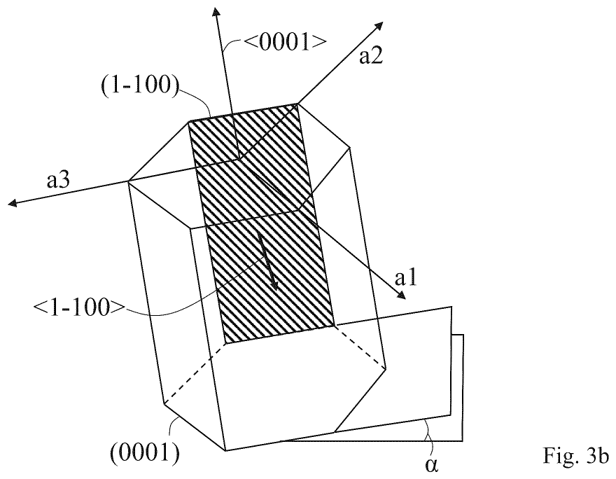

FIG. 3a shows an orientation of a lattice cell in a semiconductor body obtained from the process described above. The (11-20) plane is the a-plane. The corresponding direction <11-20> is the a-direction, to which the orientation of the first and second side wall 21, 22 as indicated in FIG. 2a refers. An averaged surface of the SiC semiconductor body is at an angle α to the <11-20> direction. In the example shown in FIG. 3a, a respective SiC wafer may for instance have a flat which is oriented along the plane (1-100), which is the m-plane (see FIG. 3b). As the a-direction points to the right we define the angle α as positive. For a negative angle α the a-direction points to the left.

In case of the first embodiment discussed above (orientation of the surface normals n₁, n₂ with respect to the 4H-SiC Crystal a-direction), the gate trench may have its length extension in the m-direction (<1-100> direction), so that the gate trench may extend perpendicular to the flat of the wafer (wafer normal tilted away from the a-plane with respect to the c-axis).

As indicated in FIG. 1 and discussed in the corresponding description, the first and second side wall 21, 22 of the gate trench may be arranged with respect to the m-direction in a second embodiment. FIG. 3b illustrates the same lattice cell like FIG. 3a, wherein the (1-100) plane, namely m-plane, is shown hatched (instead of the a-plane in FIG. 3a). The side walls of the gate trench, which are arranged with respect to the m-direction, may respectively lie parallel to the m-plane. The gate trench then may have its length extension in the a-direction.

FIG. 4 shows a detailed view of the insulating layer 60 with the contact plug 70. It is arranged in a contact hole 80 which extends through the insulating layer 60. The sectional plane of FIG. 4 lies parallel to the vertical direction 100 and to the transverse direction 101. Side walls 81, 82 of the contact hole 80, which define the contact hole 80 in the transverse direction 101, are respectively at an angle δ to the vertical direction 100. The angle δ may be at most 10°, e.g. 5° in the example shown. It may even become zero, the side walls 81, 82 lying parallel to the vertical direction 100.

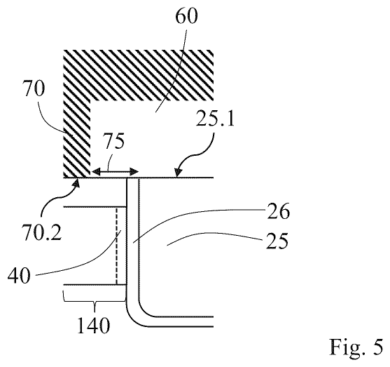

FIG. 5 shows another detailed view and illustrates a relative arrangement of the contact plug 70 and the gate electrode 25. Between a lower end 70.2 of the contact plug 70 and an upper end 25.1 of the gate electrode, a lateral distance 75 is taken. It may be in a range from 100 nm-500 nm.

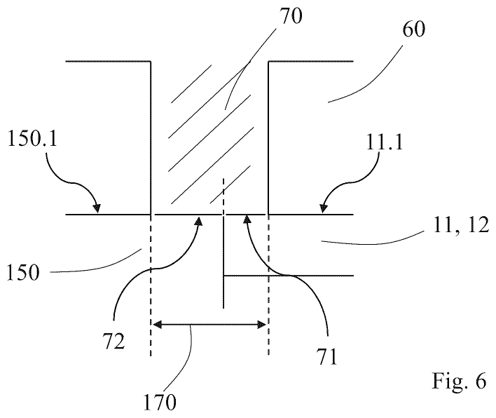

FIG. 6 shows another detailed view of the contact plug 70 in the insulating layer 60 and illustrates a first contact area 71 and a second contact area 72 of the contact plug 70. With the first contact area 71, the contact plug 70 makes electrical contact to the first load terminal 11, e.g. to at least a part of an upper surface 11.1 of the first load terminal 11. Via the second contact area 72, the electrical contact 70 makes electrical contact to the second diode region 150 (of the neighboring device cell, see FIG. 1). As illustrated in FIG. 6, the second contact area 72 may contact at least a part of an upper surface 150.1 of the second diode region 150.

The first and the second contact area 71, 72 have a different size. In the example shown, the first load terminal 11 is n-doped and the second diode region 150 is p-doped, wherein the second contact area 72 is larger than the first contact area 71, e.g. by 30%-100%. Independently of the split between the first and second contact area 71, 72, the contact plug 70 may have a lateral width 170 at its lower end 70.2 of at least 600 nm, e.g. 800 nm in the example shown.

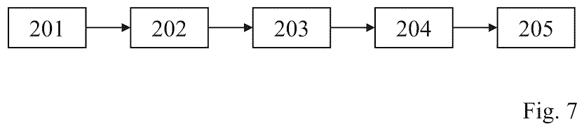

FIG. 7 summarizes some manufacturing steps in a flow diagram. Manufacturing a die may comprise etching 201 a gate trench into the SiC semiconductor body, e.g. a plurality of an elongated gate trenches arranged in parallel to each other. Then, the gate trench may be filled 202, for instance by forming the gate dielectric and gate electrode. After a deposition the 203 of the insulating layer onto the SiC semiconductor body, the contact hole may be etched 204 into the insulating layer. Then, the contact plug may be formed 205, e.g. as a separate contact plug, or together with the metallization formed on the insulating layer.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor transistor device, comprising:
a gate trench in a silicon carbide (SiC) semiconductor body;
a channel region at a first side wall of the gate trench;
a diode region at a second side wall of the gate trench,
wherein the first side wall and the second side wall lie opposite to each other in a transverse direction,
wherein, as seen in a vertical cross-section perpendicular to the first side wall and to the second side wall of the gate trench:
i) a first surface normal n₁, which is perpendicular to the first side wall and points towards the channel region, is rotated between 174° to 178° in relation to a 4H-SiC Crystal a-direction, and a second surface normal n₂, which is perpendicular to the second side wall and points towards the diode region, is rotated between −2° to −6° in relation to the 4H-SiC Crystal a-direction; or
ii) the first surface normal n₁ is rotated between −2° to 2° in relation to a 4H-SiC Crystal m-direction, and the second surface normal n₂ is rotated between 178° to 182° in relation to the 4H-SiC Crystal m-direction.

2. The semiconductor transistor device of claim 1, wherein the gate trench has the first side wall and the second side wall oriented according to i) and a length extension along a <1-100> direction.

3. The semiconductor transistor device of claim 1, wherein the first side wall and the second side wall are oriented according to i) and are, respectively taken as an absolute value, tilted by the same angle to the 4H-SiC Crystal a-plane.

4. The semiconductor transistor device of claim 1, wherein the first surface normal n₁ is oriented according to i) and rotated between 175° to 177° in relation to the 4H-SiC Crystal a-direction.

5. The semiconductor transistor device of claim 1, wherein the second surface normal n₂ is oriented according to i) and rotated between −3° to −5° in relation to the 4H-SiC Crystal a-direction.

6. The semiconductor transistor device of claim 1, wherein the gate trench has the first side wall and the second side wall oriented according to ii) and a length extension along a <11-20> direction.

7. The semiconductor transistor device of claim 1, further comprising:
an insulating layer on a first side of the SiC semiconductor body; and
a contact plug in a contact hole extending through the insulating layer,
wherein a first side wall of the contact hole, as viewed in a vertical cross-section perpendicular to the first side wall of the contact hole, forms an angle δ of at most 10° to a vertical direction.

8. The semiconductor transistor device of claim 7, wherein the first side wall and a second side wall of the contact hole, as viewed in the vertical cross-section, lie basically parallel to each other and to the vertical direction, such that the first side wall and the second side wall of the contact hole are tilted by no more than 1° as viewed in the vertical cross-section.

9. The semiconductor transistor device of claim 7, wherein a lateral distance between a lower end of the contact plug and an upper end of a gate electrode arranged in the gate trench is at most 500 nm.

10. The semiconductor transistor device of claim 7, wherein the contact plug has, taken at a lower end of the contact plug in the transverse direction, a lateral width of at least 600 nm.

11. The semiconductor transistor device of claim 1, further comprising:
a first load terminal of a first device cell at a first side of the SiC semiconductor body;
a contact plug contacting the first load terminal; and
a second diode region of a second device cell,
wherein the contact plug also contacts the second diode region, the contact plug having a first contact area to the first load terminal and a second contact area to the second diode region,
wherein the first contact area and the second contact area have a different size.

12. The semiconductor transistor device of claim 11, wherein the first contact area is larger than the second contact area.

13. The semiconductor transistor device of claim 12, wherein the first contact area is larger by at least 20% and/or at most 150% than the second contact area.

14. The semiconductor transistor device of claim 11, wherein the contact plug has, taken at a lower end of the contact plug in the transverse direction, a lateral width of at least 600 nm.

15. The semiconductor transistor device of claim 1, further comprising:
an insulating layer on a first side of the SiC semiconductor body, wherein the insulating layer comprises a borophosphosilicate (BPSG) layer with a boron content of at most 3%.

16. The semiconductor transistor device of claim 1, further comprising:
an insulating layer on a first side of the SiC semiconductor body,
wherein the insulating layer comprises a borophosphosilicate (BPSG) layer with a phosphorus content of at most 4%.

17. A method of manufacturing a semiconductor transistor device, the method comprising:
etching a gate trench into a silicon carbide (SiC) semiconductor body, the gate trench having a first side wall and a second side wall, wherein the first side wall and the second side wall lie opposite to each other in a transverse direction, wherein, as seen in a vertical cross-section perpendicular to the first side wall and to the second side wall of the gate trench: i) a first surface normal n₁, which is perpendicular to the first side wall and points towards the channel region, is rotated between 174° to 178° in relation to a 4H-SiC Crystal a-direction, and a second surface normal n₂, which is perpendicular to the second side wall and points towards the diode region, is rotated between −2° to −6° in relation to the 4H-SiC Crystal a-direction; or ii) the first surface normal n₁ is rotated between −2° to 2° in relation to a 4H-SiC Crystal m-direction, and the second surface normal n₂ is rotated between 178° to 182° in relation to the 4H-SiC Crystal m-direction; and
etching a contact hole into an insulating layer on a first side of the SiC semiconductor body, wherein a side wall of the contact hole, as viewed in a vertical cross-section perpendicular to the side wall of the contact hole, forms an angle δ of at most 10° to a vertical direction.

18. A method of manufacturing a semiconductor transistor device, the method comprising:
etching a gate trench into a silicon carbide (SiC) semiconductor body, the gate trench having a first side wall and a second side wall, wherein the first side wall and the second side wall lie opposite to each other in a transverse direction, wherein, as seen in a vertical cross-section perpendicular to the
first side wall and to the second side wall of the gate trench: i) a first surface normal n₁, which is perpendicular to the first side wall and points towards the channel region, is rotated between 174° to 178° in relation to a 4H-SiC Crystal a-direction, and a second surface normal n₂, which is perpendicular to the second side wall and points towards the diode region, is rotated between −2° to −6° in relation to the 4H-SiC Crystal a-direction; or ii) the first surface normal n₁ is rotated between −2° to 2° in relation to a 4H-SiC Crystal m-direction, and the second surface normal n₂ is rotated between 178° to 182° in relation to the 4H-SiC Crystal m-direction; and
forming a contact plug having a first contact area and a second contact area, wherein the first contact area and the second contact area have a different size.
